(19) United States
(12) Patent Application Publication
(10) Pub. No.: US 2014/0000679 A1
(43) Pub. Date: Jan. 2, 2014

(54) THIN FILM SOLAR CELL MODULE AND METHOD OF MANUFACTURING THE SAME

(71) Applicant: SAMSUNG SDI CO., LTD., Yongin-si (KR)

(72) Inventors: Young-Kyoung Ahn, Yongin-si (KR); Jung-Yup Yang, Yongin-si (KR); Bong-Kyoung Park, Yongin-si (KR); Yury Lebedev, Yongin-si (KR)

(73) Assignee: SAMSUNG SDI CO., LTD., Yongin-si (KR)

(21) Appl. No.: 13/633,824

(22) Filed: Oct. 2, 2012

Related U.S. Application Data
(60) Provisional application No. 61/665,736, filed on Jun. 28, 2012.

(51) Int. Cl. H01L 31/042; H01L 31/0224; H01L 31/18; H01L 31/0216

(52) U.S. Cl. 136/249; 136/256; 438/64; 257/E31.117

(57) ABSTRACT

A thin film solar cell module and a method of manufacturing a thin film solar cell module. A thin film solar cell module includes: a thin film solar cell including a first substrate, and a first electrode layer on the first substrate; a second substrate covering the thin film solar cell; and a sealing tape between the thin film solar cell and the second substrate, the sealing tape including a first adhesive layer having a conductivity and being attached to an edge portion of the first electrode layer; a metal layer on the first adhesive layer; and a second adhesive layer on the metal layer and attached to the second substrate.

### CROSS-REFERENCE TO RELATED APPLICATION

This application claims priority to and the benefit of U.S. Provisional Application No. 61/665,736, filed on Jun. 28, 2012 in the U.S. Patent and Trademark Office, the entire content of which is incorporated herein by reference.

### BACKGROUND

1. Field

Aspects of embodiments of the present invention relate to a thin film solar cell module and a method of manufacturing the same.

2. Description of the Related Art

The depletion of existing energy resources such as oil and coal is expected to continue and, thus, interest in alternative sources of energy has increased. From among these alternative sources, solar cells for directly transforming solar energy into electric energy by using semiconductor elements are regarded as next-generation battery cells.

Solar cells use a p-n junction and utilize various devices, such as monocrystalline solar cell, polycrystalline solar cell, amorphous silicon solar cell, compound solar cell, dye-sensitized solar cell, etc., according to their materials, to improve efficiency and characteristics. Among these solar cells, widely utilized crystalline silicon solar cells have a high cost of materials and involve complicated processing, relative to a power generation efficiency. Thus, to solve problems of crystalline silicon solar cells, interest in thin film solar cells having a low cost of production has increased.

Thin film solar cell modules include thin film solar cells, and generally additionally have an edge sealing between a lower substrate and a cover substrate so as to protect the thin film solar cells from external moisture, etc.

### SUMMARY

According to aspects of embodiments of the present invention, a thin film solar cell module is configured to prevent or substantially prevent external moisture from penetrating into the thin film solar cell module, even when edge sealing is omitted, and a method of manufacturing the same is provided.

According to an embodiment of the present invention, a thin film solar cell module includes: a thin film solar cell including a first substrate, and a first electrode layer on the first substrate; a second substrate covering the thin film solar cell; and a sealing tape between the thin film solar cell and the second substrate, the sealing tape including a first adhesive layer having a conductivity and being attached to an edge portion of the first electrode layer; a metal layer on the first adhesive layer; and a second adhesive layer on the metal layer and attached to the second substrate.

The second adhesive layer may cover outer side surfaces of the first adhesive layer and the metal layer.

The second adhesive layer may cover an outer side surface of the first electrode layer.

The second adhesive layer may contact the first substrate.

The second adhesive layer may cover inner side surfaces of the first adhesive layer and the metal layer that are opposite the outer side surfaces.

The sealing tape may include a pair of sealing tapes that are electrically connected to the thin film solar cell.

The first adhesive layer may include an adhesive film and conductive particles exposed to the outside of the adhesive film and electrically connecting the first electrode layer and the metal layer.

The second adhesive layer may include at least one of butyl resin, acrylic resin, epoxy resin, or phenoxy resin to seal the first electrode layer, the first adhesive layer, and the metal layer from external moisture.

The thin film solar cell may further include a light absorption layer, a buffer layer, and a second electrode layer sequentially stacked on the first electrode layer.

The thin film solar cell module may further include an encapsulation layer covering the second electrode layer.

The second adhesive layer may extend between the encapsulation layer and side surfaces of the first adhesive layer and the metal layer.

The thin film solar cell module may further include a pattern portion in the second electrode layer and extending to the first electrode layer, the pattern portion forming a plurality of photoelectric conversion units.

According to another embodiment of the present invention, a method of manufacturing a thin film solar cell module includes: forming a first electrode layer on a first substrate; covering the first electrode layer with a second substrate; and attaching a sealing tape between an edge portion of the first electrode layer and the second substrate, the sealing tape including a first adhesive layer having a conductivity, a metal layer on the first adhesive layer, and a second adhesive layer on the metal layer, and attaching the sealing tape includes attaching the first adhesive layer to the edge portion of the first electrode layer, and attaching the second adhesive layer to the second substrate.

The method may further include covering side surfaces of the first adhesive layer and the metal layer with the second adhesive layer. Before covering the side surfaces of the first adhesive layer and the metal layer with the second adhesive layer, a thickness of the second adhesive layer may be five to ten times greater than a thickness of the metal layer.

The method may further include: forming a light absorption layer on the first electrode layer; forming a buffer layer on the light absorption layer; and forming a second electrode layer on the buffer layer.

The method may further include: patterning a first pattern portion in the first electrode layer to expose the first substrate; and patterning a second pattern portion in the buffer layer and the light absorption layer to expose the first electrode layer, forming the light absorption layer on the first electrode layer including forming the light absorption layer on the first substrate exposed by the first pattern portion, and forming the second electrode layer on the buffer layer including forming the second electrode layer on the first electrode layer exposed by the second pattern portion.

The method may further include patterning a pattern portion in the second electrode layer and extending to the first electrode layer to form a plurality of photoelectric conversion units.

The method may further include: removing the first electrode layer, the light absorption layer, the buffer layer, and the second electrode layer from an edge portion of the first substrate; and exposing the edge portion of the first electrode layer.

The method may further include covering the second electrode layer with an encapsulation layer.

According to an aspect of embodiments of the present invention, even when edge sealing is omitted, moisture is prevented or substantially prevented from penetrating into a thin film solar cell module.

According to another aspect of embodiments of the present invention, edge sealing is omitted, and thus a process of manufacturing a thin film solar cell module is simplified.

### BRIEF DESCRIPTION OF THE DRAWINGS

The accompanying drawings, together with the specification, illustrate some exemplary embodiments of the present invention, and, together with the description, serve to explain principles and aspects of the present invention.

FIG. 1 is a schematic cross-sectional view of a thin film solar cell module according to an embodiment of the present invention; and

FIGS. 2 through 8 are schematic cross-sectional views illustrating a method of manufacturing a thin film solar cell module according to an embodiment of the present invention.

### DESCRIPTION OF REFERENCE NUMERALS INDICATING SOME ELEMENTS OF THE DRAWINGS

| | |
|---|---|
| 100: thin film solar cell module | 120: thin film solar cell |
| 121: lower substrate | 122: rear electrode layer |
| 124: light absorption layer | 126: buffer layer |
| 128: transparent electrode layer | 130: sealing tape |
| 150: encapsulation layer | 160: cover substrate |

### DETAILED DESCRIPTION

In the following detailed description, certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals refer to like elements throughout.

In the drawings, elements or features may be exaggerated, omitted, or schematically illustrated for convenience and clarity of description, and sizes thereof do not necessarily fully reflect actual sizes. Also, in the description of the elements, where an element is referred to as being “on” or “under” another element, the element may be directly on or under the other element, or indirectly on or under the other element with intervening elements. The terms “on” or “under” may be described with respect to the drawings, but are not intended to be limiting as pertains to orientation. Further, descriptions of features or aspects within each embodiment should typically be considered as available for other similar features or aspects in other embodiments.

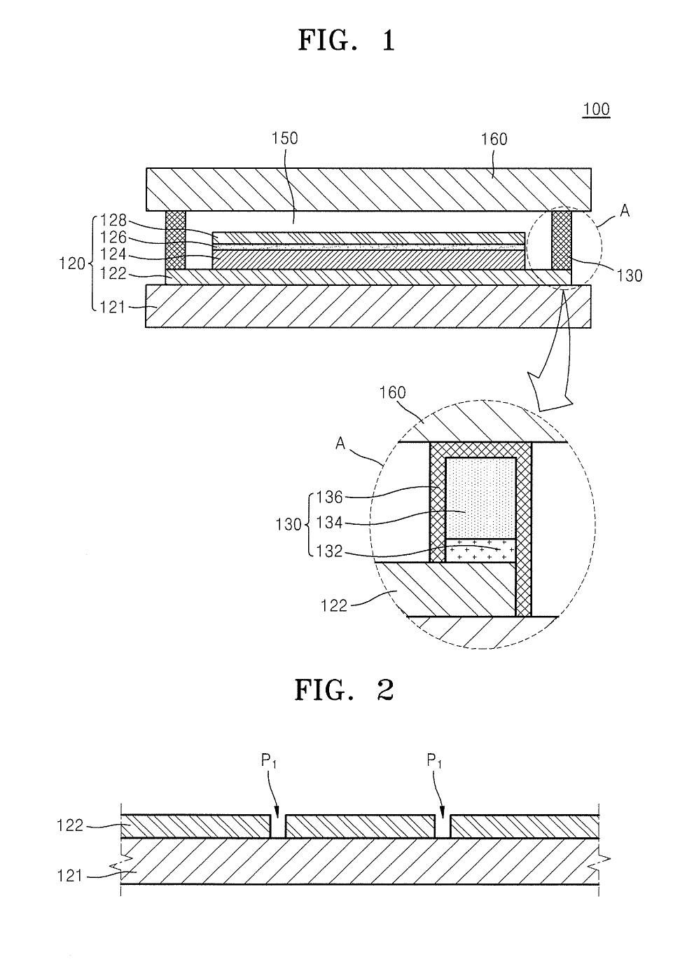

FIG. 1 is a schematic cross-sectional view of a thin film solar cell module 100 according to an embodiment of the present invention.

Referring to FIG. 1, the thin film solar cell module 100 according to an embodiment of the present invention includes a thin film solar cell 120, a conductive sealing tape 130 attached to sides of the thin film solar cell 120, an encapsulation layer 150 that seals the thin film solar cell 120, and a cover substrate 160.

The thin film solar cell 120 is a device that directly transforms solar light energy into electric energy by using a photoelectric effect and may be a CIGS thin film solar cell, an amorphous silicon thin film solar cell, a CdTd thin film solar cell, or any other suitable thin film solar cell. Although the thin film solar cell 120 is hereinafter referred to as the CIGS thin film solar cell, the present invention is not limited thereto.

For example, the thin film solar cell 120 may be an amorphous silicon thin film solar cell or a CdTd thin film solar cell.

The thin film solar cell 120, in one embodiment, includes a lower substrate 121, and a rear electrode layer 122, a light absorption layer 124, a buffer layer 126, and a transparent electrode layer 128 that are sequentially stacked on the lower substrate 121.

The lower substrate 121 may be a glass substrate, a polymer substrate, or a substrate formed of any other suitable material. For example, the lower substrate 121 may be a glass substrate formed of soda-lime glass or high strain point soda glass, or a polymer substrate formed of polyimide. However, the present invention is not limited thereto.

The rear electrode layer 122 may be formed of a metallic material having excellent conductivity and light reflectivity, such as molybdenum (Mo), aluminum (Al), or copper (Cu) in order to collect charges formed by the photoelectric effect and reflect light that transmits the light absorption layer 124 to allow the light absorption layer 124 to reabsorb the light. In one embodiment, the rear electrode layer 122 may be formed of molybdenum (Mo) in consideration of high conductivity, an ohmic contact with the light absorption layer 124, a high temperature stability at an atmosphere of selenium (Se), etc. In one embodiment, the rear electrode layer 122 may be formed as a multilayer so as to secure a junction with the lower substrate 121 and a resistance characteristic of the rear electrode layer 122.

The light absorption layer 124 may be formed of a copper-indium-gallium-selenide (Cu(In,Ga)Se₂,CIGS)-based compound including copper (Cu), indium (In), gallium (Ga), and selenide to form a P-type semiconductor layer, and absorbs incident solar light. The light absorption layer 124, in one embodiment, may be formed having a thickness between about 0.7 μm and about 2 μm by a suitable process.

The buffer layer 126 reduces a band gap difference between the light absorption layer 124 and the transparent electrode layer 128 described further below, and reduces recombination of electrons and holes that may occur at an interface between the light absorption layer 124 and the transparent electrode layer 128. The buffer layer 126 may be formed of CdS, ZnS, In₂S₃, ZnₓMg₍₁₋ₓ₎O, etc.

The transparent electrode layer 128 constitutes a P-N junction and is formed of a conductive material having a property capable of transmitting light, such as ZnO:B, ITO or IZO, etc. Thus, the transparent electrode layer 128 may transmit incident light and concurrently, or simultaneously, collect charges formed by the photoelectric effect.

The sealing tape 130, in one embodiment, includes a pair of conductive sealing tapes 130 that are attached onto the rear electrode layer 122 having a top surface exposed at both sides of the thin film solar cell 120. The sealing tapes 130, in one embodiment, collect electrons and holes that occur in the thin film solar cell 120, and are electrically connected to a junction box (not shown) that prevents or substantially prevents a counterflow of current. Also, the pair of sealing tapes 130 may seal the thin film solar cell module 100 to prevent or substantially prevent external moisture from penetrating into the thin film solar cell module 100. That is, the pair of sealing tapes 130 may concurrently, or simultaneously, act as a ribbon and perform edge sealing.

Referring to a region “A” of FIG. 1 that is an enlarged view of the sealing tape 130, the sealing tape 130, in one embodiment, includes a first adhesive layer 132, a metal layer 134 disposed on the first adhesive layer 132, and a second adhesive layer 136 that surrounds the first adhesive layer 132 and the metal layer 134.

The first adhesive layer 132 bonds the rear electrode layer 122 and the metal layer 134 to each other, and has conductivity such that charges may move from the rear electrode layer 122 to the metal layer 134. The first adhesive layer 132, in one embodiment, may be formed by dispersing conductive particles formed of gold, silver, nickel, or copper, for example, having excellent conductivity into an adhesive film formed of epoxy resin, acrylic resin, polyimide resin, or polycarbonate resin, for example. Conductive particles that are dispersed in the adhesive film may be exposed to the outside of the adhesive film, such as by processing (e.g., laminating), and electrically connect the rear electrode layer 122 and the metal layer 134.

The metal layer 134 is a main path through which collected charges move and, in one embodiment, may be formed by coating a metal layer formed of copper, gold, silver, or nickel, for example, with tin, for example.

The second adhesive layer 136, in one embodiment, may be formed of butyl resin, acrylic resin, epoxy resin, or phenoxy resin, for example, having excellent adhesion and low moisture penetration and may be used to attach the metal layer 134 and the cover substrate 160 to each other, thereby sealing the thin film solar cell module 100 and preventing or substantially preventing external moisture from penetrating into the thin film solar cell module 100.

The second adhesive layer 136 is formed to surround the first adhesive layer 132 and the metal layer 134. In one embodiment, the second adhesive layer 136 is formed on exterior (i.e. outer) surfaces of the metal layer 134, the first adhesive layer 132, and the lower electrode layer 122 and interior (i.e. inner) surfaces of the first metal layer 134 and the first adhesive layer 132.

As described above, in one embodiment, the second adhesive layer 136 is formed on the exterior surfaces of the metal layer 134, the first adhesive layer 132, and the lower electrode layer 122, thereby preventing or substantially preventing the metal layer 134, the first adhesive layer 132, and the lower electrode layer 122 from being corroded due to exposure to an external environment. The second adhesive layer 136 may also be formed on the interior surfaces of the first metal layer 134 and the first adhesive layer 132, thereby preventing or substantially preventing external moisture from penetrating into the thin film solar cell module 100 secondarily.

The encapsulation layer 150 may be disposed between the pair of sealing tapes 130 and seal the thin film solar cell 120, together with the pair of sealing tapes 130, thereby blocking moisture or oxygen that may adversely affect the thin film solar cell 120.

The encapsulation layer 150 may be formed of ethylene vinyl acetate (EVA) copolymer resin, polyvinyl butyral (PVB), EVA partial oxide, silicon resin, ester-based resin, or olefin-based resin, for example. However, the present invention is not limited thereto.

The cover substrate 160 may be formed of glass in such a way that sunlight may be transmitted through the cover substrate 160, and, in one embodiment, may be formed of tempered glass so as to protect the thin film solar cell 120 from an external shock, etc. The cover substrate 160, in one embodiment, may be formed of low-iron tempered glass so as to prevent or substantially preventing solar light from being reflected and increase transmittance of solar light.

FIGS. 2 through 8 are schematic cross-sectional views illustrating a method of manufacturing a thin film solar cell module, such as the thin film solar cell module 100 described above, according to an embodiment of the present invention.

FIGS. 2 through 4 show a structure of the thin film solar cell 120 and illustrate a method of manufacturing the thin film solar cell module 100 of FIG. 1. FIGS. 5 through 8 further illustrate the method of manufacturing the thin film solar cell module 100 by using the thin film solar cell 120 manufactured in FIGS. 2 through 4, for example.

A method of manufacturing the thin film solar cell 120 according to an embodiment of the present invention is described below with reference to FIGS. 2 through 4.

Referring to FIG. 2, in one embodiment, the rear electrode layer 122 is formed on the lower substrate 121 as a whole, first patterning is performed thereon, and the rear electrode layer 122 is divided into a plurality of layers.

The rear electrode layer 122, in one embodiment, may be formed by applying a conductive paste on the lower substrate 121 and thermally processing the conductive paste, or through processing such as plating. In one embodiment, the rear electrode layer 122 may be formed through sputtering using a molybdenum (Mo) target.

The first patterning may be performed, for example, by laser scribing. The laser scribing, in one embodiment, is performed by irradiating a laser from a bottom surface of the lower substrate 121 to the lower substrate 121 and evaporating a part of the rear electrode layer 122, and thus a first pattern portion P1 that divides the rear electrode layer 122 into a plurality of layers, such as with uniform gaps therebetween, may be formed.

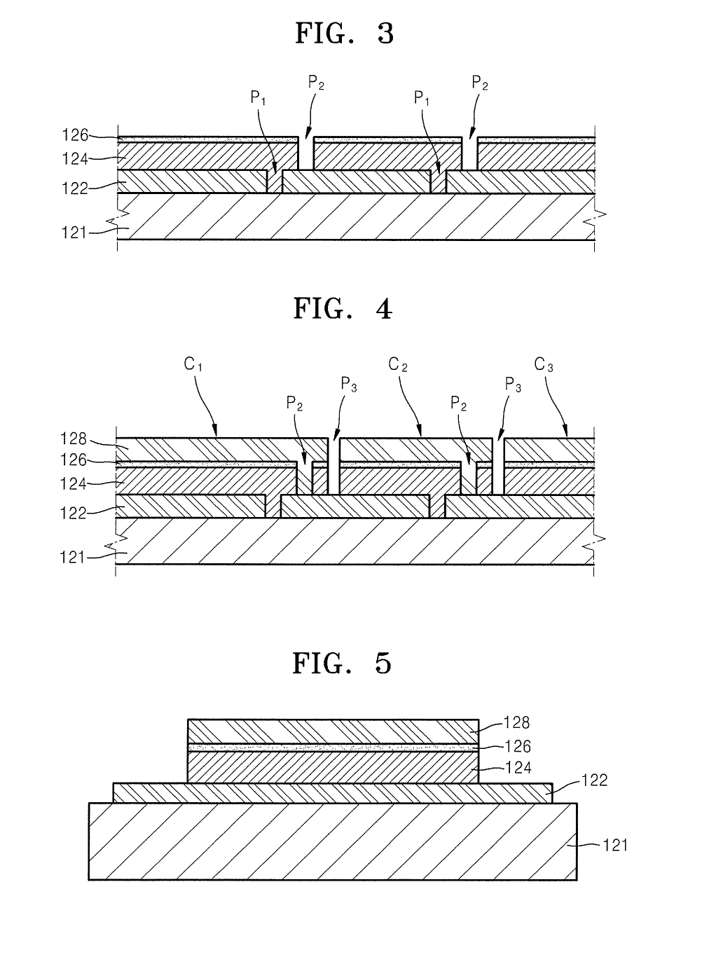

Thereafter, in one embodiment, referring to FIG. 3, the light absorption layer 124 and the buffer layer 126 are formed, and then second patterning is performed thereon.

In one embodiment, the light absorption layer 124 may be formed using i) a co-evaporation method of heating copper (Cu), indium (In), gallium (Ga), and selenium (Se) contained in a small electric furnace installed in a vacuum chamber and performing vacuum and evaporation thereon, and ii) a sputtering/selenization method of forming a CIG-based metal precursor layer on the rear electrode layer 122 by using a copper (Cu) target, an indium (In) target, and a gallium (Ga) target, thermally processing the CIG-based metal precursor layer in an atmosphere of hydrogen selenide (H₂Se), and reacting the CIG-based metal precursor layer with selenium (Se). In one embodiment, the light absorption layer 124 may be formed using an electro-deposition method, a molecular organic chemical vapor deposition (MOCVD) method, etc.

The buffer layer 126, in one embodiment, may be formed using a chemical bath deposition (CBD) method, an atomic layer deposition (ALD) method, an ion layer gas reaction (ILGAR) method, etc.

The second patterning, in one embodiment, may be performed by mechanical scribing that is performed to form a second pattern portion P2 by moving a sharp tool such as a needle in a direction parallel to the first pattern portion P1 at a point spaced apart from the first pattern portion P1. However, the present invention is not limited thereto. For example, the second patterning may be performed by laser scribing.

The second pattern portion P2 divides the light absorption layer 124 into a plurality of layers and extends to a top surface of the rear electrode layer 122 to allow the rear electrode layer 122 to be exposed.

Referring to FIG. 4, in one embodiment, the transparent electrode layer 128 is formed, and third patterning is subsequently performed.

The transparent electrode layer 128 may be formed of a transparent and conductive material such as ZnO:B, ITO, or IZO, for example, and may be formed using a metalorganic chemical vapor deposition (MOCVD), a low pressure chemical vapor deposition (LPCVD), or a sputtering method, for example.

The transparent electrode layer 128, in one embodiment, is formed in the second pattern portion P2 to contact the rear electrode layer 122 exposed by the second pattern portion P2 and electrically connect the light absorption layer 124 that is divided into the plurality of layers by the second pattern portion P2.

The transparent electrode layer 128, in one embodiment, may be divided into a plurality of layers by a third pattern portion P3 formed at a location different from the first pattern portion P1 and the second pattern portion P2.

The third patterning, in one embodiment, may be performed by mechanical scribing. The third pattern portion P3 formed by performing the third patterning may be a groove formed in parallel with the first pattern portion P1 and the second pattern portion P2, and extend to the top surface of the rear electrode layer 122, such that a plurality of photoelectric conversion units C1, C2, and C3 may be formed. Also, the third pattern portion P3 may act as an insulation layer between the photoelectric conversion units C1, C2, and C3 to connect the photoelectric conversion units C1, C2, and C3 in series with each other.

The method of manufacturing the thin film solar cell module 100 of FIG. 1 is described further below with reference to FIGS. 5 through 8.

Referring to FIG. 5, edge deletion is performed on the thin film solar cell 120 of FIG. 4, and then the top surface of the rear electrode layer 122 is exposed to attach the pair of sealing tapes 130 thereto.

The edge deletion is a process of removing the rear electrode layer 122, the light absorption layer 124, the buffer layer 126, and the transparent electrode layer 128 formed on edges of the lower substrate 121, and thus a bonding force between the sealing tapes 130 and the lower substrate 121 may be increased. The edge deletion may be performed using mechanical scribing or laser scribing, for example.

After the edge deletion is performed, both ends of the rear electrode layer 122 are exposed through mechanical scribing, laser scribing, or selective etching, for example. The sealing tapes 130 are attached onto the exposed rear electrode layer 122, and, in one embodiment, a width of the exposed rear electrode layer 122 may be greater than that of the pair of sealing tapes 130 in consideration of a processing error, etc.

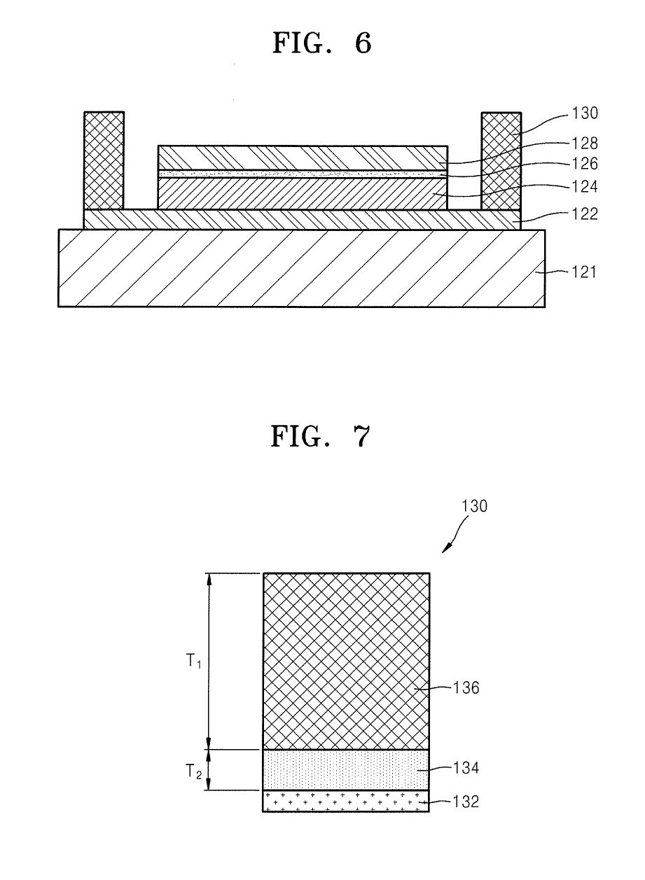

Referring to FIG. 6, the sealing tapes 130 are attached onto the exposed top surface of the rear electrode layer 122. In one embodiment, the pair of sealing tapes 130 may be disposed extending in a direction of a side of the rear electrode layer 122 in parallel with the first through third pattern portions P1 through P3. In one embodiment, although not shown, each of the sealing tapes 130 may have a shape “ [symbol] ” so as to seal the thin film solar cell module 100 (e.g., having an oblong shape) as a whole.

FIG. 7 is a cross-sectional view of the sealing tape 130 as attached onto the rear electrode layer 122. Referring to FIG. 7, the sealing tape 130, in one embodiment, includes the first adhesive layer 132, the metal layer 134, and the second adhesive layer 136 that are sequentially stacked. In one embodiment, a thickness T₁ of the second adhesive layer 136 may be five to ten times greater than a thickness T₂ of the metal layer 134.

As described below, in one embodiment, at least a part of the second adhesive layer 136 may melt during laminating and flow downward along side surfaces of the metal layer 134 and the first adhesive layer 132 located under the second adhesive layer 136, and thus the second adhesive layer 136 covers the side surfaces of the metal layer 134 and the first adhesive layer 132. Therefore, the metal layer 134 and the first adhesive layer 132 are blocked from an external environment, thereby preventing or substantially preventing the metal layer 134 and the first adhesive layer 132 from being corroded and preventing or substantially preventing external moisture from penetrating into the thin film solar cell module 100.

However, in a case where the thickness T₁ of the second adhesive layer 136 is less than five times greater than the thickness T₂ of the metal layer 134, the second adhesive layer 136 may not sufficiently cover the side surfaces of the metal layer 134 and the first adhesive layer 132 during laminating, and thus the metal layer 134 and the first adhesive layer 132 may be exposed to the outside, which may result in corrosion of the metal layer 134 and the first adhesive layer 132 and may not prevent or substantially prevent external moisture from penetrating into the thin film solar cell module 100.

Further, in a case where the thickness T₁ of the second adhesive layer 136 is more than ten times greater than the thickness T₂ of the metal layer 134, since the thickness of the pair of sealing tapes 130 is very great, the second adhesive layer 136 that melts during laminating may penetrate into a top surface of the encapsulation layer 150. In this case, a bonding force between the encapsulation layer 150 and the cover substrate 160 may be weakened, which may reduce or deteriorate a sealing effect, and incident light may be partially blocked by the second adhesive layer 136, which reduces efficiency of the thin film solar cell module 100.

Therefore, in one embodiment, the thickness T₁ of the second adhesive layer 136 is five to ten times greater than the thickness T₂ of the metal layer 134.

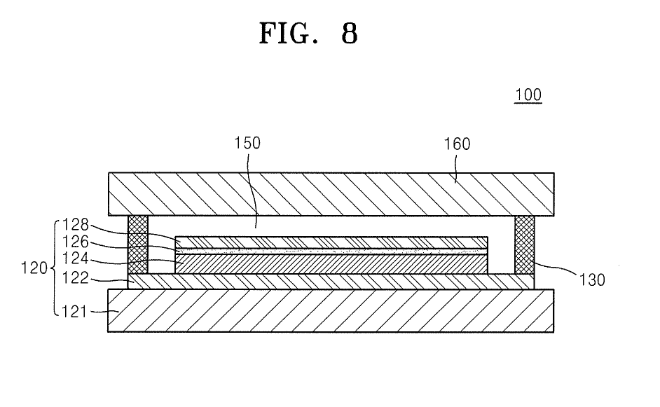

Referring to FIG. 8, after the sealing tapes 130 are attached onto the rear electrode layer 122, the encapsulation layer 150 and the cover substrate 160 may be disposed to form the thin film solar cell module 100, such as through laminating.

The encapsulation layer 150 is disposed between the sealing tapes 130 and seals the thin film solar cell module 100, such as through laminating.

In one embodiment, at least a part of the second adhesive layer 136 melts during laminating and flows downward along the side surfaces of the metal layer 134 and the first adhesive layer 132 due to gravity, and thus the second adhesive layer 136 is formed to surround the first adhesive layer 132 and the metal layer 134. Therefore, the metal layer 134 and the first adhesive layer 132 are blocked from an external environment, thereby preventing or substantially preventing the metal layer 134 and the first adhesive layer 132 from being corroded and preventing or substantially preventing external moisture from penetrating into the thin film solar cell module 100.

According to an embodiment of the present invention, the sealing tapes 130 concurrently, or simultaneously, act as a ribbon and perform edge sealing, and thus edge sealing may be omitted. Furthermore, because edge sealing may be omitted, a process of manufacturing the thin film solar cell module 100 may be simplified. Furthermore, since edge sealing may be omitted, an area of the thin film solar cell 120 may be increased, thereby enhancing photoelectric conversion efficiency of the thin film solar cell module 100.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A thin film solar cell module comprising:
a thin film solar cell comprising:
a first substrate; and
a first electrode layer on the first substrate;
a second substrate covering the thin film solar cell; and
a sealing tape between the thin film solar cell and the second substrate, the sealing tape comprising:
a first adhesive layer having a conductivity and being attached to an edge portion of the first electrode layer;
a metal layer on the first adhesive layer; and
a second adhesive layer on the metal layer and attached to the second substrate.

2. The thin film solar cell module of claim 1, wherein the second adhesive layer covers outer side surfaces of the first adhesive layer and the metal layer.

3. The thin film solar cell module of claim 2, wherein the second adhesive layer covers an outer side surface of the first electrode layer.

4. The thin film solar cell module of claim 3, wherein the second adhesive layer contacts the first substrate.

5. The thin film solar cell module of claim 2, wherein the second adhesive layer covers inner side surfaces of the first adhesive layer and the metal layer that are opposite the outer side surfaces.

6. The thin film solar cell module of claim 1, wherein the sealing tape comprises a pair of sealing tapes that are electrically connected to the thin film solar cell.

7. The thin film solar cell module of claim 1, wherein the first adhesive layer comprises an adhesive film and conductive particles exposed to the outside of the adhesive film and electrically connecting the first electrode layer and the metal layer.

8. The thin film solar cell module of claim 1, wherein the second adhesive layer comprises at least one of butyl resin, acrylic resin, epoxy resin, or phenoxy resin to seal the first electrode layer, the first adhesive layer, and the metal layer from external moisture.

9. The thin film solar cell module of claim 1, wherein the thin film solar cell further comprises a light absorption layer, a buffer layer, and a second electrode layer sequentially stacked on the first electrode layer.

10. The thin film solar cell module of claim 9, further comprising an encapsulation layer covering the second electrode layer.

11. The thin film solar cell module of claim 10, wherein the second adhesive layer extends between the encapsulation layer and side surfaces of the first adhesive layer and the metal layer.

12. The thin film solar cell module of claim 9, further comprising a pattern portion in the second electrode layer and extending to the first electrode layer, the pattern portion forming a plurality of photoelectric conversion units.

13. A method of manufacturing a thin film solar cell module, the method comprising:
forming a first electrode layer on a first substrate;
covering the first electrode layer with a second substrate; and
attaching a sealing tape between an edge portion of the first electrode layer and the second substrate,
wherein the sealing tape comprises a first adhesive layer having a conductivity, a metal layer on the first adhesive layer, and a second adhesive layer on the metal layer, and
wherein attaching the sealing tape comprises attaching the first adhesive layer to the edge portion of the first electrode layer, and attaching the second adhesive layer to the second substrate.

14. The method of claim 13, further comprising covering side surfaces of the first adhesive layer and the metal layer with the second adhesive layer.

15. The method of claim 14, wherein, before covering the side surfaces of the first adhesive layer and the metal layer with the second adhesive layer, a thickness of the second adhesive layer is five to ten times greater than a thickness of the metal layer.

16. The method of claim 13, further comprising:
forming a light absorption layer on the first electrode layer;
forming a buffer layer on the light absorption layer; and
forming a second electrode layer on the buffer layer.

17. The method of claim 16, further comprising:
patterning a first pattern portion in the first electrode layer to expose the first substrate; and
patterning a second pattern portion in the buffer layer and the light absorption layer to expose the first electrode layer,
wherein forming the light absorption layer on the first electrode layer comprises forming the light absorption layer on the first substrate exposed by the first pattern portion, and
wherein forming the second electrode layer on the buffer layer comprises forming the second electrode layer on the first electrode layer exposed by the second pattern portion.

18. The method of claim 16, further comprising patterning a pattern portion in the second electrode layer and extending to the first electrode layer to form a plurality of photoelectric conversion units.

19. The method of claim 16, further comprising:
removing the first electrode layer, the light absorption layer, the buffer layer, and the second electrode layer from an edge portion of the first substrate; and
exposing the edge portion of the first electrode layer.

20. The method of claim 16, further comprising covering the second electrode layer with an encapsulation layer.
